(19) United States
(12) Patent Application Publication
(10) Pub. No.: US 2025/0046544 A1
(43) Pub. Date: Feb. 6, 2025

(54) MECHANICAL KEY COMPONENT AND MECHANICAL KEYBOARD

(71) Applicant: PIXART IMAGING INC., HSIN-CHU (TW)

(72) Inventors: CHE-CHIA HSU, HSIN-CHU (TW); CHI-CHIEH LIAO, HSIN-CHU (TW); YU-HAN CHEN, HSIN-CHU (TW)

(21) Appl. No.: 18/924,142

(22) Filed: Oct. 23, 2024

Related U.S. Application Data
(63) Continuation-in-part of application No. 17/859,072, filed on Jul. 7, 2022, now Pat. No. 12,154,732.
Application No. 17/859,072 is a continuation-in-part of application No. 16/843,570, filed on Apr. 8, 2020, now Pat. No. 11,418,193.

(30) Foreign Application Priority Data
Jun. 20, 2024 (CN) 202410800273.8

(51) Int. Cl. H01H 13/807; H01H 13/14

(52) U.S. Cl. CPC H01H 13/807; H01H 13/14

(57) ABSTRACT

A mechanical key component and a mechanical keyboard are provided. The mechanical key component includes a circuit board, an elastic element and a key cap. The circuit board is provided with a first sensing electrode. The elastic element is disposed on the circuit board, and a movable portion of the elastic element is connected to a second sensing electrode. The key cap is movably disposed on the elastic element. The elastic element enables the key cap to move between an unpressed position and a pressed position, and the movable portion drives the second sensing electrode to move relative to the first sensing electrode. In response to the key cap being moved between the unpressed position and the pressed position, a coupling capacitance between the first sensing electrode and the second sensing electrode changes to indicate whether the key cap is in the unpressed position or the pressed position.

### CROSS-REFERENCE TO RELATED PATENT APPLICATION

This application claims the benefit of priority to China Patent Application No. 202410800273.8, filed on Jun. 20, 2024, in the People's Republic of China. The entire content of the above identified application is incorporated herein by reference.

This application is a continuation-in-part application of the U.S. patent application Ser. No. 17/859,072, filed on Jul. 7, 2022, and entitled “KEY UNIT,” which is a continuation-in-part of U.S. application Ser. No. 16/843,570, filed on Apr. 8, 2020 and entitled “KEY UNIT AND KEYBOARD USING THE SAME,” now issued as the U.S. Pat. No. 11,418,193, the entire disclosures of which are incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a key component and a keyboard, and more particularly to a mechanical key component and a mechanical keyboard using a capacitive sensor.

### BACKGROUND OF THE DISCLOSURE

In existing mechanical keyboards, a signal is triggered by an independent mechanical switch under each key. In general, a mechanical key axis can be divided into a shaft, a spring, and conductive metal parts for short-circuit triggering. When the key is pressed, the shaft will drive the conductive metal parts. When two of the conductive metal parts come into contact, a short circuit is triggered and a signal is generated. When the key is released, the spring provides a rebound force.

However, during a process where the two conductive metal parts come into contact and trigger the short circuit, their mechanical structures will experience an unstable state caused by the collision and rebound of the two parts. Hence, before being able to determine whether the key is pressed, it is necessary to wait until the two conductive metal parts come in stable contact and output a signal, such as to result in input delays.

Therefore, improvement of the sensing mechanism to avoid input delays caused by the mechanical structure has become one of the important issues in the relevant art.

### SUMMARY OF THE DISCLOSURE

In response to the above-referenced technical inadequacies, the present disclosure provides a mechanical key component and a mechanical keyboard capable of achieving low delay by using a capacitive sensor.

In order to solve the above-mentioned problems, one of the technical aspects adopted by the present disclosure is to provide a mechanical key component, including a circuit board, an elastic element and a key cap. The circuit board has a first sensing electrode. The elastic element is disposed on the circuit board, and a movable portion of the elastic element is connected to a second sensing electrode. The key cap is movably disposed on the elastic element, the elastic element enables the key cap to move between an unpressed position and a pressed position, and the movable portion drives the second sensing electrode to move relative to the first sensing electrode without contacting the first sensing electrode. When a first sensing signal is provided to at least one of the first sensing electrode and the second sensing electrode, a coupling capacitance is formed between the first sensing electrode and the second sensing electrode, and in response to the key cap being moved between the unpressed position and the pressed position, the coupling capacitance changes to indicate whether the key cap is in the unpressed position or the pressed position. In response to the key cap moving between the unpressed position and the pressed position along a first direction, the movable portion drives the second sensing electrode to move relative to the first sensing electrode along a second direction, the second direction is parallel to a surface of the circuit board, and the first direction is perpendicular to the second direction.

In order to solve the above-mentioned problems, another one of the technical aspects adopted by the present disclosure is to provide a mechanical keyboard, including a plurality of mechanical key components and a processing circuit. Each of the plurality of mechanical key components includes a circuit board with a first sensing electrode, an elastic element and a key cap. The elastic element is disposed on the circuit board, and a movable portion of the elastic element is connected to a second sensing electrode. The key cap is movably disposed on the elastic element, in which the elastic element enables the key cap to move between an unpressed position and a pressed position, and the movable portion drives the second sensing electrode to move relative to the first sensing electrode without contacting the first sensing electrode. The processing circuit is electrically connected to the mechanical key components, in which the processing circuit is configured to perform the following processes: providing a first sensing signal to at least one of the first sensing electrode and the second sensing electrode; obtaining a coupling capacitance generated between the first sensing electrode and the second sensing electrode; and detecting, in response to the key cap being moved between the unpressed position and the pressed position, a change in the coupling capacitance to indicate whether the key cap is in the unpressed position or the pressed position. In response to the key cap moving between the unpressed position and the pressed position along a first direction, the movable portion drives the second sensing electrode to move relative to the first sensing electrode along a second direction, the second direction is parallel to a surface of the circuit board, and the first direction is perpendicular to the second direction.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a mechanical key component in an unpressed position according to a first embodiment of the present disclosure;

FIG. 2 is a schematic perspective view of the mechanical key component according to the first embodiment of the present disclosure;

FIG. 3 is a schematic side view of the mechanical key component in a pressed position according to the first embodiment of the present disclosure;

FIG. 4 is another schematic side view of the mechanical key component in an unpressed position according to the first embodiment of the present disclosure;

FIG. 5 is another schematic side view of the mechanical key component in a pressed position according to the first embodiment of the present disclosure;

FIG. 6 is another schematic side view of the mechanical key component in an unpressed position according to the first embodiment of the present disclosure;

FIG. 7 is yet another schematic side view of the mechanical key component in a pressed position according to the first embodiment of the present disclosure;

FIG. 8 is yet another schematic side view of the mechanical key component in an unpressed position according to the first embodiment of the present disclosure;

FIG. 9 is still another schematic side view of the mechanical key component in a pressed position according to the first embodiment of the present disclosure;

FIG. 10 is still another schematic side view of the mechanical key component in an unpressed position according to the first embodiment of the present disclosure;

FIG. 11 is still another schematic side view of the mechanical key component in an unpressed position according to the first embodiment of the present disclosure;

FIG. 12 is a schematic side view of a mechanical key component in an unpressed position according to a second embodiment of the present disclosure;

FIG. 13 is a schematic side view of the mechanical key component in a pressed position according to the second embodiment of the present disclosure;

FIG. 14 is another schematic side view of the mechanical key component in an unpressed position according to the second embodiment of the present disclosure;

FIG. 15 is another schematic side view of the mechanical key component in a pressed position according to the second embodiment of the present disclosure;

FIG. 16 is yet another schematic side view of the mechanical key component in an unpressed position according to the second embodiment of the present disclosure;

FIG. 17 is yet another schematic side view of the mechanical key component in a pressed position according to the second embodiment of the present disclosure;

FIG. 18 is still another schematic side view of the mechanical key component in an unpressed position according to the second embodiment of the present disclosure;

FIG. 19 is still another schematic side view of the mechanical key component in a pressed position according to the second embodiment of the present disclosure;

FIG. 20 is a schematic top view of a keyboard according to a third embodiment of the present disclosure; and

FIG. 21 is a functional block diagram of the keyboard according to the third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

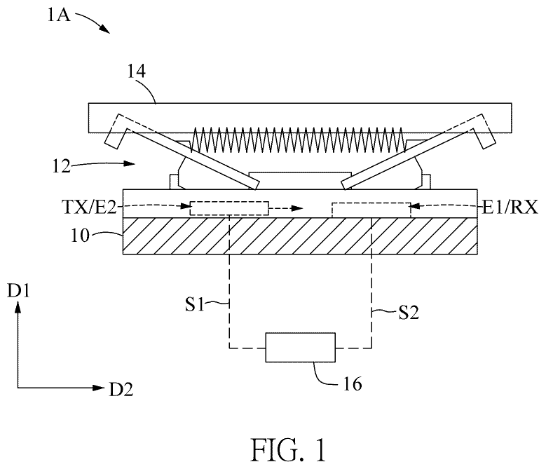

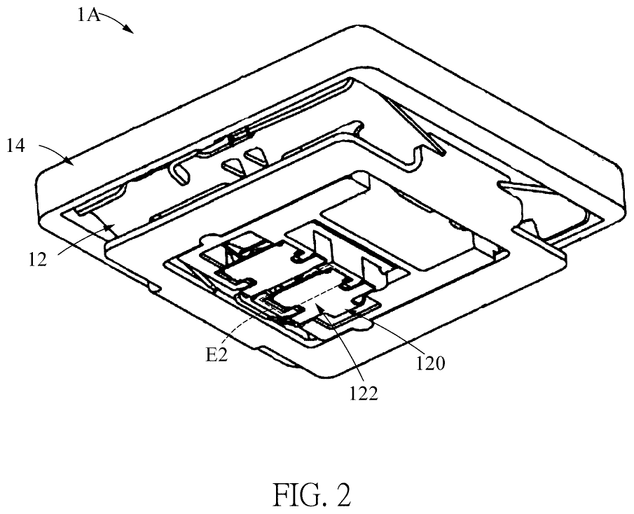

FIG. 1 is a schematic side view of a mechanical key component in an unpressed position according to a first embodiment of the present disclosure. FIG. 2 is a schematic perspective view of the mechanical key component according to the first embodiment of the present disclosure. Referring to FIG. 1 and FIG. 2, the first embodiment of the present disclosure mainly provides a mechanical key component 1A based on an axis-type mechanical keyboard, and the mechanical key component 1A includes a circuit board 10, an elastic element 12 and a key cap 14. The circuit board 10 can be, for example, a conductive board or a printed circuit board. A first sensing electrode E1 is disposed on the circuit board 10. It should be noted that the mechanical key component 1A provided by the present disclosure can be applied to any keyboard, which can be electrically connected to a personal computer or integrated with a housing or a host housing of other device components.

As shown in FIG. 1, the elastic element 12 is disposed on the circuit board 10. In one embodiment, the elastic element 12 is compressible and resilient, and the elastic element 12 is connected between the circuit board 10 and the key cap 14, such that the key cap 14 can be movably disposed on the circuit board 10. That is, the key cap 14 can be moved between an unpressed position and a pressed position relative to the circuit board 10. In addition, the elastic element 12 can, for example, include a double-wing structure for supporting the key cap 14, and a scissor-type structure and a spring element that enable the key cap 14 to move between the unpressed position and the pressed position, but this is merely an example and the present disclosure is not limited thereto.

In addition, as shown in FIG. 2, the elastic element 12 has a movable portion 120 located at a side of the elastic element 12 where the key cap 14 is not disposed, and the movable portion 120 is connected to the second sensing electrode E2. The key cap 14 is disposed on the elastic element 12. When the elastic element 12 enables the key cap 14 to move between the unpressed position and the pressed position, the movable portion 120 can simultaneously allow the second sensing electrode E2 to move relative to the first sensing electrode E1 without contacting the first sensing electrode E1. The first sensing electrode E1 and the second sensing electrode E2 can be made of conductive materials, such as metallic conductive materials.

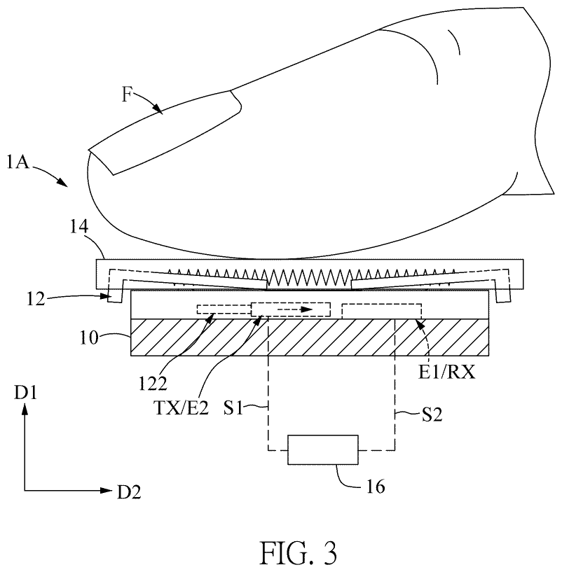

Reference is made to FIG. 3, which is a schematic side view of the mechanical key component in a pressed position according to the first embodiment of the present disclosure. When the key cap 14 is pressed (for example, pressed by a finger F), the key cap 14 moves along a first direction D1 from the unpressed position to the pressed position, and at the same time, the movable portion 120 drives the second sensing electrode E2 to move along a second direction D2 relative to the first sensing electrode E1, and the first direction D1 is perpendicular to the second direction D2. For example, the first direction D1 can be a normal direction of the circuit board 10, and the second direction D2 can be a direction that is parallel to a surface of the circuit board 10. In this embodiment, the second sensing electrode E2 is fixed on the movable portion 120 by a limiting element 122 and moves only along the second direction D2, and the first sensing electrode E1 is fixedly disposed on the circuit board 10.

When a first sensing signal is provided to at least one of the first sensing electrode E1 and the second sensing electrode E2, for example, when a bias voltage is applied to the first sensing electrode E1 or the second sensing electrode E2, an electric field can be generated between the first sensing electrode E1 and the second sensing electrode E2. Therefore, when the key cap 14 moves between the unpressed position and the pressed position, a variation in the distance between the first sensing electrode E1 and the second sensing electrode E2 will cause a change in the electric field, thereby changing a coupling capacitance between the first sensing electrode E1 and the second sensing electrode E2. It should be noted that a change in the coupling capacitance can be used to indicate whether the key cap 14 is in the unpressed position or the pressed position.

Referring to FIG. 1, the first sensing electrode E1 and the second sensing electrode E2 can be electrically connected to a detection circuit 16. It should be noted that the embodiment of FIG. 1 is a mutual capacitance structure, the second sensing electrode E2 is a transmitting end for transmitting a first sensing signal S1, the first sensing electrode E1 is a receiving end for receiving the second sensing signal S2, and a magnitude of the second sensing signal S2 corresponds to the coupling capacitance between the first sensing electrode E1 and the second sensing electrode E2. In this way, a state of the mechanical key component 1A can be determined by detecting the coupling capacitance between the first sensing electrode E1 and the second sensing electrode E2.

However, the present disclosure is not limited thereto. In the mutual capacitance structure, the first sensing electrode E1 can be a transmitting end for transmitting the first sensing signal S1, and the second sensing electrode E2 can be a receiving end for receiving the second sensing signal S2. The coupling capacitance between the first sensing electrode E1 and the second sensing electrode E2 can also be detected.

Therefore, the mechanical key component 1A provided by the present disclosure does not utilize the existing contact short-circuit detection, but determine a change of a distance between the first sensing electrode E1 and the second sensing electrode E2 according to the change of the coupling capacitance. Therefore, the two sensing electrodes can determine whether the mechanical key component 1A is in the pressed position or the unpressed position without contact, so as to eliminate a wait time required for conductive metal parts utilized in the existing mechanical keyboard to come in stable contact before outputting a signal, thereby achieving low input delay.

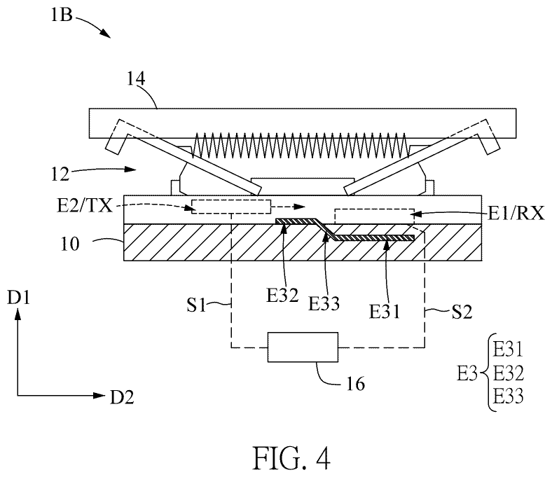

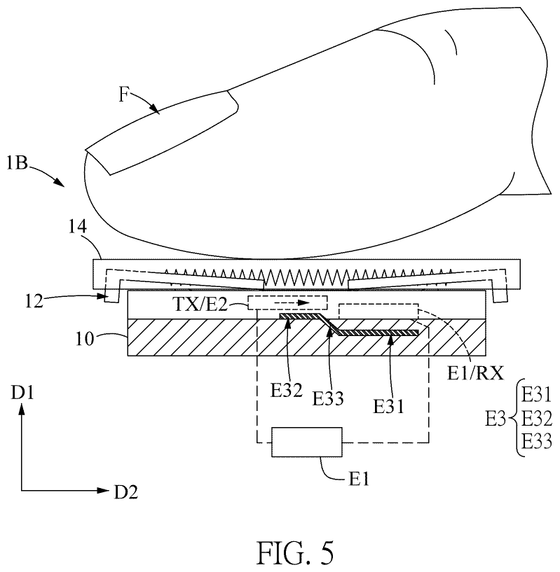

FIG. 4 is another schematic side view of the mechanical key component in an unpressed position according to the first embodiment of the present disclosure. FIG. 5 is another schematic side view of the mechanical key component in a pressed position according to the first embodiment of the present disclosure. Referring to FIGS. 4 and 5, the first embodiment of the present disclosure also provides a mechanical key component 1B, including a circuit board 10, an elastic element 12 and a key cap 14. The structures of FIG. 4 and FIG. 1 are basically the same, except that the mechanical key component 1B further includes a third sensing electrode E3, and at least a portion of the third sensing electrode E3 overlaps with the first sensing electrode E1 in a normal direction of the circuit board 10 without a change in position. In addition, the third sensing electrode E3 is electrically floating, and at least a part of the third sensing electrode E3 is located in the circuit board 10. The third sensing electrode E3 and the first sensing electrode E1 can overlap in the normal direction of the circuit board 10 and do not contact the first sensing electrode E1 and the second sensing electrode E2.

In the embodiments of FIGS. 4 and 5, the third sensing electrode E3 can include a first portion E31 and a second portion E32, and the second portion E32 is closer to the second sensing electrode E2 than the first portion E31. In the unpressed position of the mechanical key component 1B, the first portion E31 overlaps with the first sensing electrode E1 in the normal direction of the circuit board 10, and the second portion E32 does not overlap with the first sensing electrode E1 and the second sensing electrode E2; when the mechanical key component 1B is pressed, the movable portion 120 drives the second sensing electrode E2 to move along a second direction D2 and change an area where the second sensing electrode E2 overlaps with the third sensing electrode E3 in the normal direction of the circuit board 10 changes; when the mechanical key component 1B is in the pressed position, the first portion E31 overlaps with the first sensing electrode E1 in the normal direction of the circuit board 10, and the second portion E32 does not overlap with the first sensing electrode E1, but overlaps with the second sensing electrode E2 in the normal direction of the circuit board 10. Thus, the third sensing electrode E3 can be used to extend a detection distance of the second sensing electrode E2, and can further increase the coupling capacitance between the transmitting end and the receiving end, thereby improving the sensing performance.

In addition, the first portion E31 and the second portion E32 of the third sensing electrode E3 respectively overlap with the first sensing electrode E1 and the second sensing electrode E2 in the normal direction of the circuit board 10 at different positions in the first direction D1 (i.e., the normal direction of the circuit board 10). The first portion E31 of the third sensing electrode E3 is embedded in the circuit board 10, while the second portion E32 is exposed on an upper surface of the circuit board 10. Therefore, the second portion E32 is closer to the second sensing electrode E2 than the first portion E31 in both the first direction D1 and the second direction D2. The third sensing electrode E3 can further include a third portion E33 disposed between the first portion E31 and the second portion E32. The third portion E33 is inclined relative to the upper surface of the circuit board 10, thereby raising the second portion E32 to a position higher than a position of the upper surface of the circuit board 10, and bringing the second portion E32 closer to the second sensing electrode E2. However, the above is only one implementation of the third sensing electrode E3, and the first portion E31, the second portion E32, and the third portion E33 can all be located in the circuit board 10. Alternatively, another implementation is for the third sensing electrode E3 to be disposed above the first sensing electrode E1 and the second sensing electrode E2. For example, the third sensing electrode E3 can be disposed in the key cap 14 and used to extend the detection distance of the second sensing electrode E2 and increase the coupling capacitance between the transmitting end and the receiving end.

As shown in FIG. 5, when the key cap 14 is pressed (for example, pressed by a finger F), the key cap 14 moves along the first direction D1 from the unpressed position to the pressed position, and at the same time, the movable portion 120 drives the second sensing electrode E2 to move relative to the first sensing electrode E1 along the second direction D2 (for example, approaching). The change in the distance between the first sensing electrode E1 and the second sensing electrode E2 changes the electric field, thereby changing the coupling capacitance between the first sensing electrode E1 and the second sensing electrode E2. The change in coupling capacitance can be used to indicate whether the key cap 14 is in the unpressed position or the pressed position.

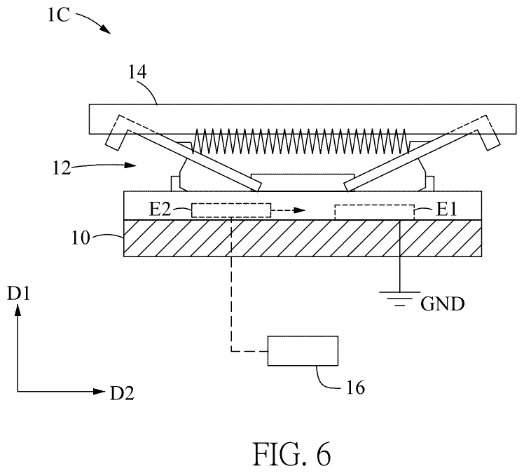

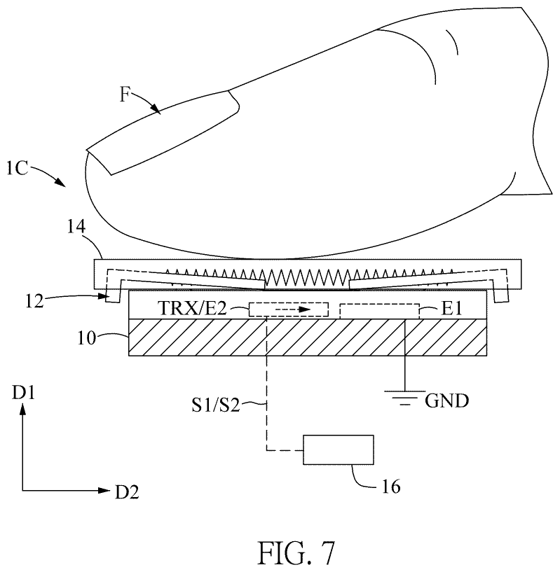

FIG. 6 is yet another schematic side view of the mechanical key component in an unpressed position according to the first embodiment of the present disclosure. FIG. 7 is yet another schematic side view of the mechanical key component in a pressed position according to the first embodiment of the present disclosure. Referring to FIGS. 6 and 7, the first embodiment of the present disclosure also provides a mechanical key component 1C, including a circuit board 10, an elastic element 12 and a key cap 14. The structures of FIG. 6 and FIG. 7 are basically the same as the structure of FIG. 1, except that, of the first sensing electrode E1 and the second sensing electrode E2, only the second sensing electrode E2 is electrically connected to the detection circuit 16, while the first sensing electrode E1 is grounded, thereby forming a self-capacitance structure.

In this self-capacitor structure, the second sensing electrode E2 serves as a transmitting-and-receiving terminal TRX for transmitting the first sensing signal S1 and receiving the second sensing signal S2, the first sensing electrode E1 serves as a ground terminal GND, and the second sensing signal S2 corresponds to the coupling capacitance. As shown in FIG. 7, for the mechanical key component 1C, when the user presses the key cap 14 with a finger (an object F), as the distance between the first sensing electrode E1 and the second sensing electrode E2 shortens, a part of charges flows into the ground terminal GND through the grounded first sensing electrode E1, thereby changing the coupling capacitance between the first sensing electrode E1 and the second sensing electrode E2.

In this way, by detecting the coupling capacitance between the first sensing electrode E1 and the second sensing electrode E2 (i.e., the coupling capacitance between the transmitting-and-receiving terminal TRX and the ground terminal GND), a state of the mechanical key component 1C can be determined. However, the present disclosure is not limited thereto.

In the self-capacitance structure, the first sensing electrode E1 can also be used as the transmitting-and-receiving terminal TRX for transmitting the first sensing signal S1 and receiving the second sensing signal S2, and the second sensing electrode E2 can also be used as the ground terminal GND. In this way, the state of the mechanical key component 1C can also be determined according to the change of the coupling capacitance between the first sensing electrode E1 and the second sensing electrode E2.

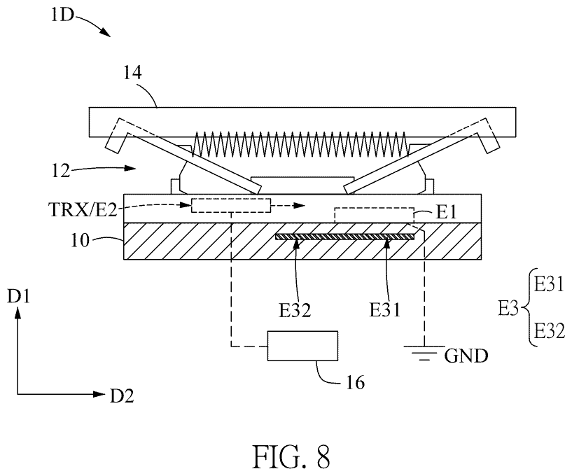

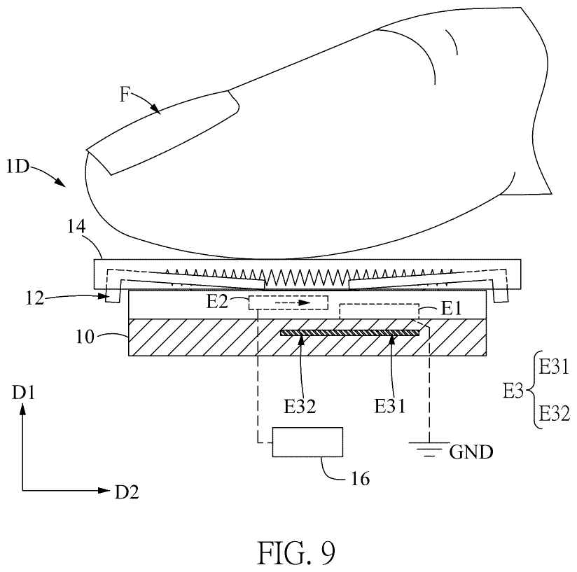

FIG. 8 is still another schematic side view of the mechanical key component in an unpressed position according to the first embodiment of the present disclosure. FIG. 9 is still another schematic side view of the mechanical key component in a pressed position according to the first embodiment of the present disclosure. Referring to FIGS. 8 and 9, the first embodiment of the present disclosure also provides a mechanical key component 1D, including a circuit board 10, an elastic element 12 and a key cap 14. The structures of FIGS. 8 and 9 are basically the same as those of FIGS. 6 and 7, except that the mechanical key component 1D further includes a third sensing electrode E3, which is electrically floating and at least partially located in the circuit board 10. The third sensing electrode E3 overlaps with the first sensing electrode E1 in the normal direction of the circuit board 10 and does not contact the first sensing electrode E1 and the second sensing electrode E2.

Similar to FIGS. 6 and 7, the second sensing electrode E2 is electrically connected to the detection circuit 16, and the first sensing electrode E1 is grounded, thereby forming a self-contained structure. In the embodiments of FIGS. 8 and 9, the third sensing electrode E3 can include a first portion E31 and a second portion E32, and the second portion E32 is closer to the second sensing electrode E2 than the first portion E31. In the unpressed position of the mechanical key component 1D, the first portion E31 overlaps with the first sensing electrode E1 in the normal direction of the circuit board 10, and the second portion E32 does not overlap with the first sensing electrode E1 and the second sensing electrode E2; when the mechanical key component 1D is pressed, the movable portion 120 drives the second sensing electrode E2 to move along a second direction D2 and change an area where the second sensing electrode E2 overlaps with the third sensing electrode E3 in the normal direction of the circuit board 10 changes; when the mechanical key component 1D is in the pressed position, the first portion E31 overlaps with the first sensing electrode E1 in the normal direction of the circuit board 10, and the second portion E32 does not overlap with the first sensing electrode E1, but overlaps with the second sensing electrode E2 in the normal direction of the circuit board 10. Thus, the third sensing electrode E3 can be used to extend a detection distance of the second sensing electrode E2, and can further increase the coupling capacitance between the transmitting-and-receiving terminal TRX and the ground terminal GND, thereby improving the sensing performance.

In addition, the first portion E31 and the second portion E32 of the third sensing electrode E3 are both embedded in the circuit board 10, and the second portion E32 is closer to the second sensing electrode E2 than the first portion E31 in the second direction D2. Alternatively, another implementation is for the third sensing electrode E3 to be disposed above the first sensing electrode E1 and the second sensing electrode E2. For example, the third sensing electrode E3 can be disposed in the key cap 14 and used to extend the detection distance of the second sensing electrode E2 and increase the coupling capacitance between the transmitting-and-receiving terminal TRX and the ground terminal GND.

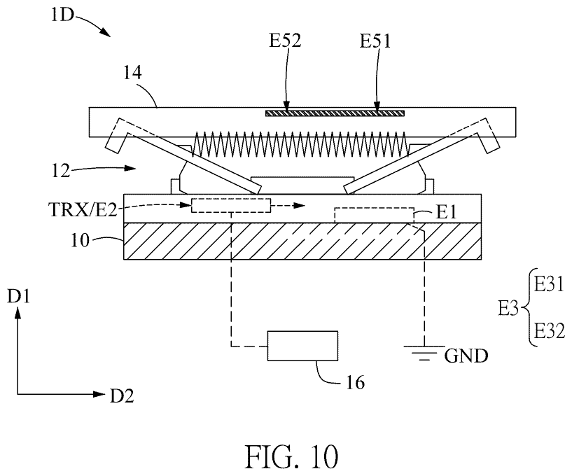

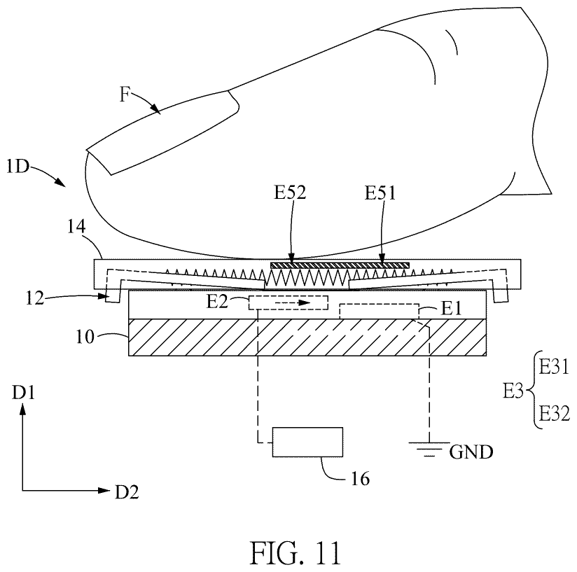

FIG. 10 is still another schematic side view of the mechanical key component in an unpressed position according to the first embodiment of the present disclosure. FIG. 11 is still another schematic side view of the mechanical key component in an unpressed position according to the first embodiment of the present disclosure. Referring to FIGS. 10 and 11, the first embodiment of the present disclosure also provides a mechanical key component 1E, including a circuit board 10, an elastic element 12 and a key cap 14. The structures of FIGS. 10 and 11 are basically the same as those of FIG. 3, except that the mechanical key component 1E further includes a fifth sensing electrode E5, at least a portion of the fifth sensing electrode E5 overlaps with the first sensing electrode E1 in the normal direction of the circuit board 10 without a change in position, and the fifth sensing electrode E5 is electrically floating and at least partially located in the key cap 14. The fifth sensing electrode E5 can overlap with the first sensing electrode E1 in the normal direction of the circuit board 10 and does not contact the first sensing electrode E1 and the second sensing electrode E2.

Similar to FIG. 3, the second sensing electrode E2 is electrically connected to the detection circuit 16, and the first sensing electrode E1 is grounded, thereby forming a self-capacitance structure. In the embodiments of FIGS. 10 and 11, the fifth sensing electrode E5 can include a first portion E51 and a second portion E52, and the second portion E52 is closer to the second sensing electrode E2 than the first portion E51. In the unpressed position of the mechanical key component 1E, the first portion E51 overlaps with the first sensing electrode E1 in the normal direction of the circuit board 10, and the second portion E52 does not overlap with the first sensing electrode E1 and the second sensing electrode E2; when the mechanical key component 1E is pressed, the movable portion 120 drives the second sensing electrode E2 to move along a second direction D2 and change an area where the second sensing electrode E2 and the fifth sensing electrode E5 in the normal direction of the circuit board 10 changes; when the mechanical key component 1E is in the pressed position, the first portion E51 overlaps with the first sensing electrode E1 in the normal direction of the circuit board 10, and the second portion E52 does not overlap with the first sensing electrode E1, but overlaps with the second sensing electrode E2 in the normal direction of the circuit board 10. Thus, the fifth sensing electrode E5 can be used to extend a detection distance of the second sensing electrode E2, and can further increase the coupling capacitance between the transmitting-and-receiving terminal TRX and the ground terminal GND, thereby improving the sensing performance.

In addition, the first portion E51 and the second portion E52 of the fifth sensing electrode E5 are both embedded in the key cap 14, and the second portion E52 is closer to the second sensing electrode E2 than the first portion E51 in the second direction D2.

### Second Embodiment

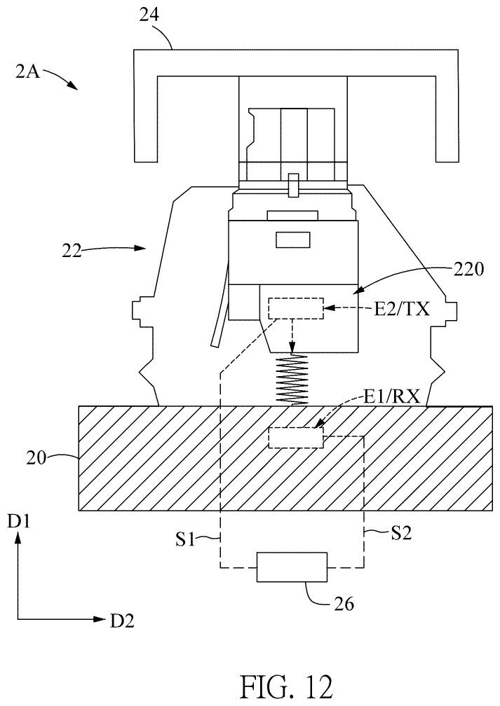

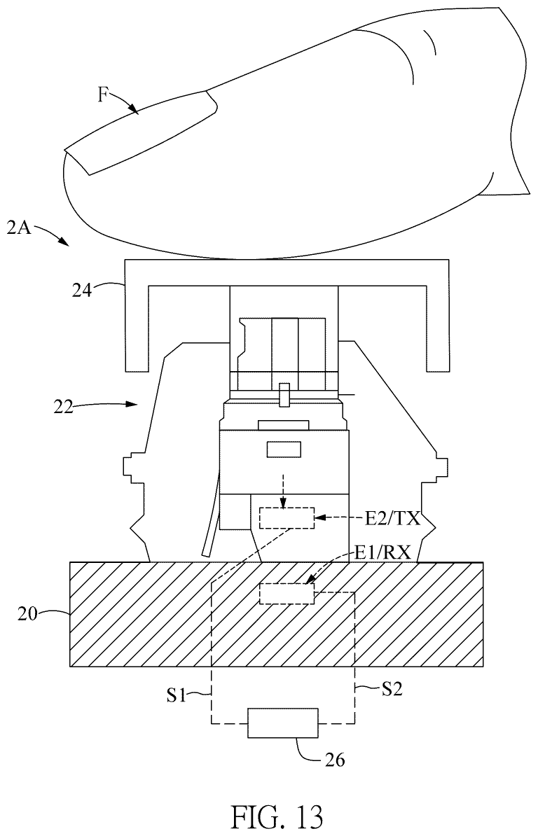

FIG. 12 is a schematic side view of a mechanical key component in an unpressed position according to a second embodiment of the present disclosure. FIG. 13 is a schematic side view of the mechanical key component in a pressed position according to the second embodiment of the present disclosure. Referring to FIGS. 12 and 13, the second embodiment of the present disclosure mainly provides a mechanical key component 2A based on an axis-type mechanical keyboard, and the mechanical key component includes a circuit board 20, an elastic element 22 and a key cap 24. Similarly, the circuit board 20 can be, for example, a conductive board or a printed circuit board, and the circuit board 20 is provided with a first sensing electrode E1. It should be noted that the mechanical key component 2A provided by the present disclosure can be applied to any keyboard, which can be electrically connected to a personal computer or integrated with a housing or a host housing of other device components.

As shown in FIG. 12, the elastic element 22 is disposed on the circuit board 20 and is compressible and resilient. The elastic element 22 is connected between the circuit board 20 and the key cap 24, such that the key cap 24 can be movably disposed on the circuit board 20. That is, the key cap 24 can move between an unpressed position and a pressed position relative to the circuit board 20. In addition, in a structure of the axis-type mechanical keyboard, the elastic element 22 can, for example, include an axis core structure, a spring element and a base, in which the axis core structure is used to support the key cap 24 and provide resistance changes. After being assembled with the spring element and the base, the key cap 24 can move between the unpressed position and the pressed position. However, this is merely an example and the present disclosure is not limited thereto.

In addition, as shown in FIG. 11, the elastic element 22 has a movable portion 220, which is located at a side where the key cap 24 is not disposed, and the movable portion 220 is connected to the second sensing electrode E2. For example, a portion of the core structure can be used as a movable structure and is used to provide the second sensing electrode E2. The key cap 24 is disposed on the elastic element 22. When the elastic element 22 enables the key cap 24 to move between the unpressed position and the pressed position, the movable portion 220 can simultaneously allow the second sensing electrode E2 to move relative to the first sensing electrode E1 without contacting the first sensing electrode E1. The first sensing electrode E1 and the second sensing electrode E2 can be made of conductive materials, such as metallic conductive materials.

Referring to FIG. 13, when the key cap 24 is pressed (for example, pressed by a finger F), the key cap 24 moves along a first direction D1 from the unpressed position to the pressed position, and at the same time, the movable portion 220 drives the second sensing electrode E2 to move along a first direction D1 relative to the first sensing electrode E1, and the first direction D1 is perpendicular to the second direction D2. For example, the first direction D1 can be a normal direction of the circuit board 20, and the second direction D2 can be a direction parallel to a surface of the circuit board 20.

When a first sensing signal is provided to at least one of the first sensing electrode E1 and the second sensing electrode E2, for example, when a bias voltage is applied to the first sensing electrode E1 or the second sensing electrode E2, an electric field can be generated between the first sensing electrode E1 and the second sensing electrode E2. Therefore, when the key cap 24 moves between the unpressed position and the pressed position, a variation in the distance between the first sensing electrode E1 and the second sensing electrode E2 will cause a change in the electric field, thereby changing a coupling capacitance between the first sensing electrode E1 and the second sensing electrode E2. It should be noted that a change in the coupling capacitance can be used to indicate whether the key cap 24 is in the unpressed position or the pressed position.

Referring to FIG. 12, the first sensing electrode E1 and the second sensing electrode E2 can be electrically connected to a detection circuit 26. It should be noted that the embodiment of FIG. 12 is a mutual capacitance structure, the second sensing electrode E2 is a transmitting end for transmitting a first sensing signal S1, the first sensing electrode E1 is a receiving end for receiving the second sensing signal S2, and a magnitude of the second sensing signal S2 corresponds to the coupling capacitance between the first sensing electrode E1 and the second sensing electrode E2. In this way, a state of the mechanical key component 1A can be determined by detecting the coupling capacitance between the first sensing electrode E1 and the second sensing electrode E2.

However, the present disclosure is not limited thereto. In the mutual capacitance structure, the first sensing electrode E1 can be a transmitting end for transmitting the first sensing signal S1, and the second sensing electrode E2 can be a receiving end for receiving the second sensing signal S2. The coupling capacitance between the first sensing electrode E1 and the second sensing electrode E2 can also be detected.

Therefore, the mechanical key component 2A provided by the present disclosure is applicable to the axis-type mechanical keyboard structure. Moreover, the mechanical key component 2A does not utilize the existing contact short-circuit detection, but determine a change of a distance between the first sensing electrode E1 and the second sensing electrode E2 according to the change of the coupling capacitance. Therefore, the two sensing electrodes can be used to determine whether the mechanical key component 2A is in the pressed position or the unpressed position without contacting with each other, thereby eliminating a wait time required for conductive metal parts utilized in the existing mechanical keyboard to come in stable contact before outputting a signal, thereby achieving low input delay.

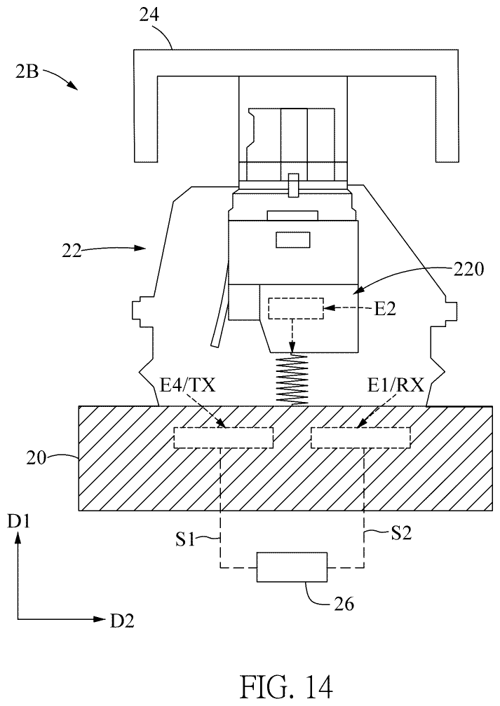

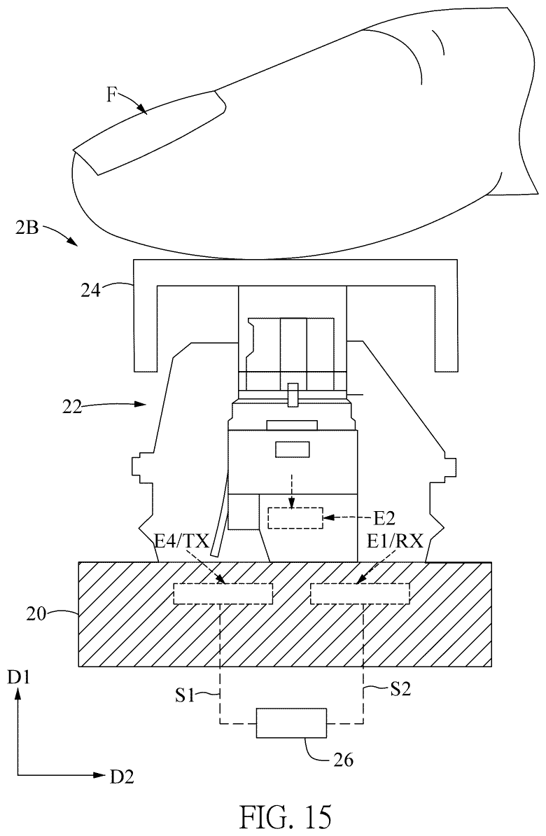

FIG. 14 is another schematic side view of the mechanical key component in an unpressed position according to the second embodiment of the present disclosure. FIG. 15 is another schematic side view of the mechanical key component in a pressed position according to the second embodiment of the present disclosure. Referring to FIGS. 14 and 15, the second embodiment of the present disclosure also provides a mechanical key component 2B, including a circuit board 20, an elastic element 22 and a key cap 24. The structures of FIGS. 14 and 15 are basically the same as those of FIGS. 12 and 13, and are both mutual capacitance structures. The difference is that the mechanical key component 2B further includes a fourth sensing electrode E4 located in the circuit board 20. In this embodiment, the second sensing electrode E2 is electrically floating, overlaps with the first sensing electrode E1 and the fourth sensing electrode E4 in the normal direction of the circuit board 10, and does not contact the first sensing electrode E1 and the fourth sensing electrode E4.

In the embodiments of FIGS. 14 and 15, the fourth sensing electrode E4 serves as a transmitting end TX for transmitting the first sensing signal S1, the first sensing electrode E1 serves as a receiving end RX for receiving the second sensing signal S2, and the second sensing signal S2 corresponds to the coupling capacitance generated among the first sensing electrode E1, the second sensing electrode E2 and the fourth sensing electrode E4.

When the mechanical key component 2B is in the unpressed position, the floating second sensing electrode E2 is distant from the first sensing electrode E1 and the fourth sensing electrode E4; when the mechanical key component 2B is in the pressed position, the floating second sensing electrode E2 is close to the first sensing electrode E1 and the fourth sensing electrode E4, thereby changing the coupling capacitance. Compared with the structure using only two sensing electrodes, the coupling capacitance between the transmitting end TX and the receiving end RX can be further increased, thereby improving the sensing performance.

When the key cap 24 is pressed (for example, pressed by a finger F), the key cap 24 moves along the first direction D1 from the unpressed position to the pressed position, and at the same time, the movable portion 220 drives the second sensing electrode E2 to move relative to the first sensing electrode E1 and the fourth sensing electrode E4 along the first direction D1 (for example, approaching). The change in the distance between the first sensing electrode E1 and the second sensing electrode E2 changes the electric field, thereby changing the coupling capacitance between the first sensing electrode E1 and the fourth sensing electrode E4. The change in coupling capacitance can be used to indicate whether the key cap 24 is in the unpressed position or the pressed position.

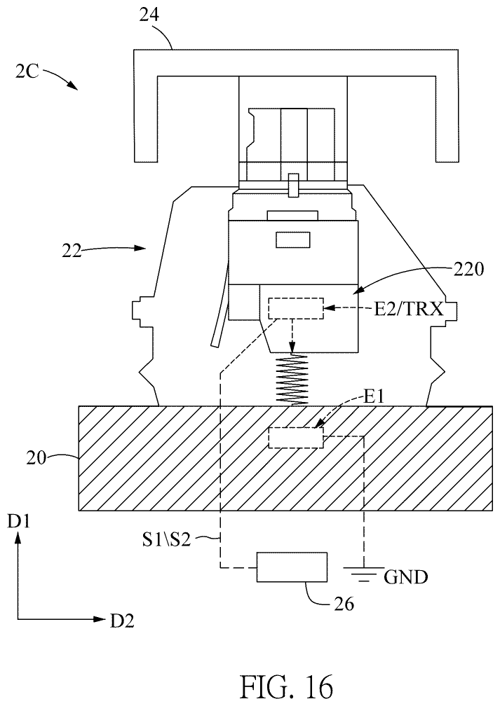

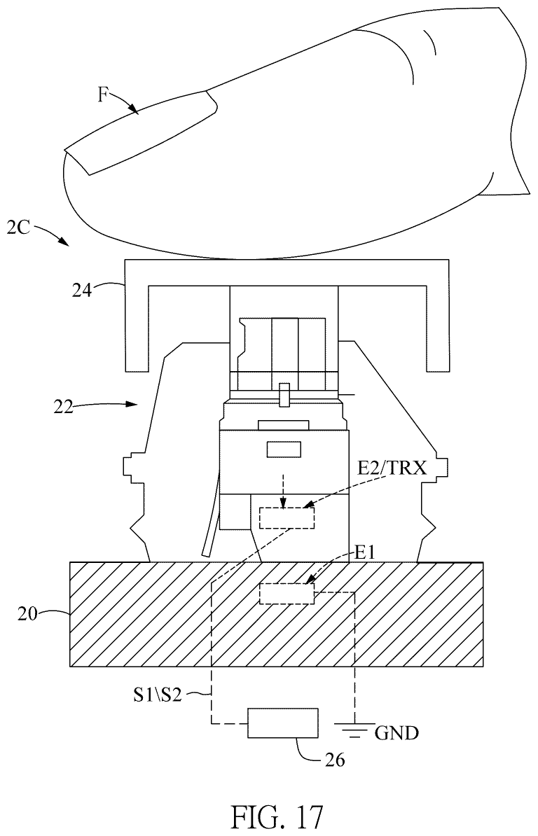

FIG. 16 is yet another schematic side view of the mechanical key component in an unpressed position according to the second embodiment of the present disclosure. FIG. 17 is yet another schematic side view of the mechanical key component in a pressed position according to the second embodiment of the present disclosure. Referring to FIGS. 16 and 17, the second embodiment of the present disclosure also provides a mechanical key component 2C, including a circuit board 20, an elastic element 22 and a key cap 24. The structures of FIGS. 16 and 17 are basically the same as those of FIGS. 12 and 13, except that, of the first sensing electrode E1 and the second sensing electrode E2, only the second sensing electrode E2 is electrically connected to the detection circuit 26, while the first sensing electrode E1 is grounded, thereby forming a self-capacitance structure.

In this self-capacitor structure, the second sensing electrode E2 serves as a transmitting-and-receiving terminal TRX for transmitting the first sensing signal S1 and receiving the second sensing signal S2, the first sensing electrode E1 serves as a ground terminal GND, and the second sensing signal S2 corresponds to the coupling capacitance. As shown in FIG. 17, for the mechanical key component 2C, when the user presses the key cap 24 with a finger (an object F), as the distance between the first sensing electrode E1 and the second sensing electrode E2 shortens, a part of charges flows into the ground terminal GND through the grounded first sensing electrode E1, thereby changing the coupling capacitance between the first sensing electrode E1 and the second sensing electrode E2.

In this way, by detecting the coupling capacitance between the first sensing electrode E1 and the second sensing electrode E2 (i.e., the coupling capacitance between the transmitting-and-receiving terminal TRX and the ground terminal GND), a state of the mechanical key component 2C can be determined.

However, the present disclosure is not limited thereto. In the self-capacitance structure, the first sensing electrode E1 can also be used as the transmitting-and-receiving terminal TRX for transmitting the first sensing signal S1 and receiving the second sensing signal S2, and the second sensing electrode E2 can also be used as the ground terminal GND. In this way, the state of the mechanical key component 2C can also be determined according to the change of the coupling capacitance between the first sensing electrode E1 and the second sensing electrode E2.

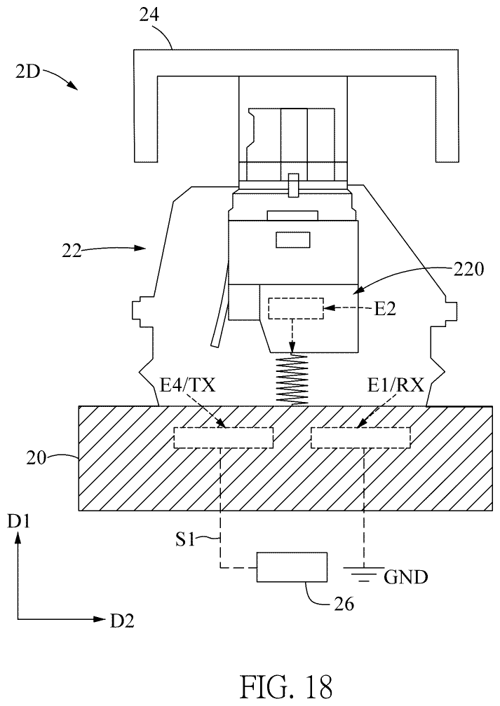

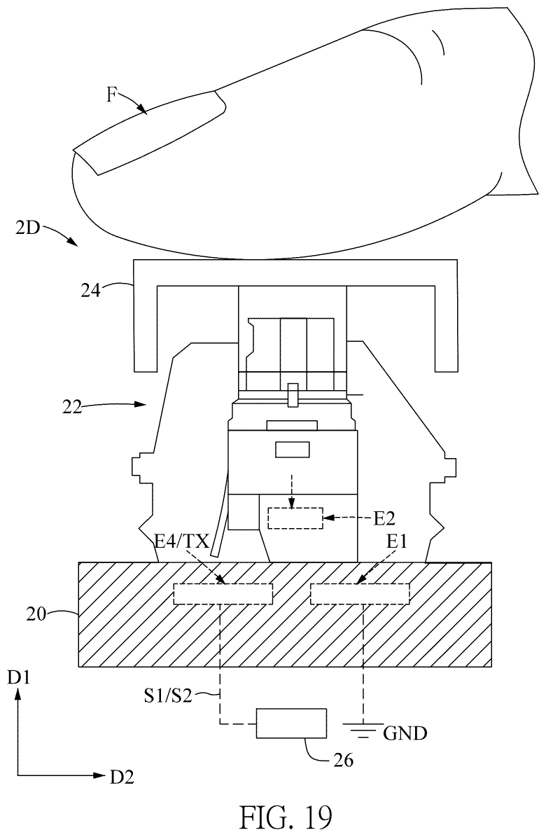

FIG. 18 is still another schematic side view of the mechanical key component in an unpressed position according to the second embodiment of the present disclosure. FIG. 19 is still another schematic side view of the mechanical key component in a pressed position according to the second embodiment of the present disclosure. Referring to FIGS. 18 and 17, the second embodiment of the present disclosure also provides a mechanical key component 2D, including a circuit board 20, an elastic element 22 and a key cap 24. The structures of FIGS. 18 and 17 are basically the same as those of FIGS. 16 and 15, except that the mechanical key component 2D further includes a fourth sensing electrode E4 located in the circuit board 20, and the second sensing electrode E2 is electrically floating, overlapping with the first sensing electrode E1 and the fourth sensing electrode E4 in the normal direction of the circuit board 20, and does not contact the first sensing electrode E1 and the fourth sensing electrode E4.

Similar to FIGS. 16 and 15, the first sensing electrode E1 is grounded, and the fourth sensing electrode E4 replaces the second sensing electrode E2 as a transmitting-and-receiving terminal TRX for transmitting the first sensing signal S1 and receiving the second sensing signal S2 and is electrically connected to the detection circuit 26, thereby forming a self-capacitance structure. The second sensing signal S2 corresponds to the coupling capacitance generated among the first sensing electrode E1, the second sensing electrode E2 and the fourth sensing electrode E4.

When the mechanical key component 2D is in the unpressed position, the floating second sensing electrode E2 is distant from the first sensing electrode E1 and the fourth sensing electrode E4; when the mechanical key component 2D is in the pressed position, the floating second sensing electrode E2 is close to the first sensing electrode E1 and the fourth sensing electrode E4, thereby changing the coupling capacitance. Compared with the structure using only two sensing electrodes, the coupling capacitance between the transmitting end TX and the receiving end RX can be further increased, thereby improving the sensing amount.

When the key cap 24 is pressed (for example, pressed by a finger F), the key cap 24 moves along the first direction D1 from the unpressed position to the pressed position, and at the same time, the movable portion 220 drives the second sensing electrode E2 to move relative to the first sensing electrode E1 and the fourth sensing electrode E4 along the first direction D1 (for example, approaching). The change in the distance between the first sensing electrode E1 and the second sensing electrode E2 changes the electric field, thereby changing the coupling capacitance, and the change in coupling capacitance can be used to indicate whether the key cap 24 is in the unpressed position or the pressed position.

### Third Embodiment

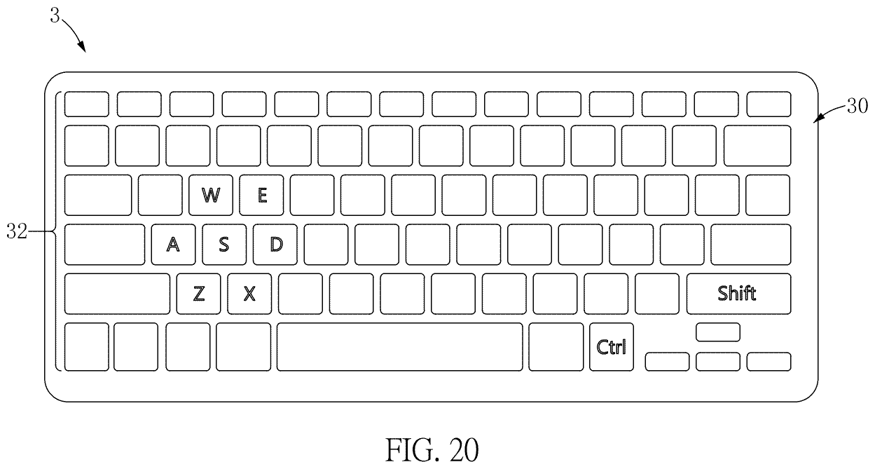

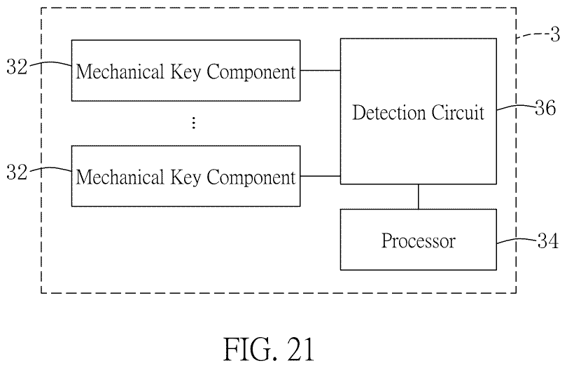

FIG. 20 is a schematic top view of a keyboard according to a third embodiment of the present disclosure, and FIG. 21 is a functional block diagram of the keyboard according to the third embodiment of the present disclosure.

As shown in FIG. 20, the mechanical keyboard 3 is an independent keyboard and is not integrated with a computer. However, in other embodiments, the mechanical keyboard 3 can be integrated with a housing or a host housing of a computer or other device component, such as a mobile device, an e-book, a computer, a laptop, a desktop computer, a stand-alone keyboard, an input device, an accessory (such as a tablet computer bag with a built-in keyboard), a screen, an electronic kiosk, a gaming device, an automated teller machine (ATM), a vehicle dashboard, a console, a medical workstation, and an industrial workstation.

The mechanical keyboard 3 can be electrically coupled to the computer or integrated with the computer as a user interface to allow the user to input commands. In addition, the mechanical keyboard 3 can also include a touch panel and other input devices, but the present disclosure is not limited to the aforementioned embodiments.

As shown in FIG. 20, the mechanical keyboard 3 includes a housing 30 and a plurality of mechanical key components 32 disposed on the housing 30 and arranged in a predetermined manner. Specifically, the housing 30 can define a space for accommodating the mechanical key components 32.

The mechanical key component 32 can be any one of the mechanical key components 1A to 1D and 2A to 2D described in the first to second embodiments. The mechanical key components 32 can be accommodated in the space defined by the housing 30. An outer surface of a key cap of each mechanical key component 32 is exposed outside the housing 30 for easy operation.

As shown in FIG. 21, the mechanical keyboard 3 further includes a processor 34 electrically connected to a detection circuit 36 to receive status information of each mechanical key component 32. In one embodiment, the processor 34 can be a programmable logic controller, a logic circuit, a microprocessor, or any combination thereof. In the present embodiment, the processor 34 is electrically connected to the detection circuit 36, which can include the detection circuits 16, 26 of the aforementioned embodiments; however, in another embodiment, the processing circuit 13 can be integrated with the detection circuits 16, 26 of the aforementioned embodiments. It should be noted that FIG. 21 only shows one of the mechanical key components 32 for exemplary purposes.

The detection circuit 36 receives a second sensing signal transmitted from each mechanical key component 32 to determine whether the key cap 14 is in the pressed position or the unpressed position. In one embodiment, status information of the plurality of mechanical key components 32 can be transmitted to the processor 34 by the same detection circuit 36.

### Beneficial Effects of the Embodiments

In conclusion, in the mechanical key component and the mechanical keyboard provided by the present disclosure, different from the existing contact short-circuit detection, a change of a distance between multiple sensing electrodes can be the determined according to a change of the coupling capacitance, and the sensing electrodes can be used to determine whether the mechanical key component is in the pressed position or the unpressed position without contacting with one another, thereby eliminating eliminating a wait time required for conductive metal parts utilized in the existing mechanical keyboard to come in stable contact before outputting a signal, thereby achieving low input delay.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A mechanical key component, comprising:
a circuit board with a first sensing electrode;
an elastic element disposed on the circuit board, wherein a movable portion of the elastic element is connected to a second sensing electrode; and
a key cap movably disposed on the elastic element, wherein the elastic element enables the key cap to move between an unpressed position and a pressed position, and the movable portion drives the second sensing electrode to move relative to the first sensing electrode without contacting the first sensing electrode;
wherein, when a first sensing signal is provided to at least one of the first sensing electrode and the second sensing electrode, a coupling capacitance is formed between the first sensing electrode and the second sensing electrode, and in response to the key cap being moved between the unpressed position and the pressed position, the coupling capacitance changes to indicate whether the key cap is in the unpressed position or the pressed position;
wherein, in response to the key cap moving between the unpressed position and the pressed position along a first direction, the movable portion drives the second sensing electrode to move relative to the first sensing electrode along a second direction, the second direction is parallel to a surface of the circuit board, and the first direction is perpendicular to the second direction.

2. The mechanical key component according to claim 1, wherein the second sensing electrode is fixed by a limiting element and moves only along the second direction, and the first sensing electrode is fixedly disposed on the circuit board.

3. The mechanical key component according to claim 2, further comprising:
a third sensing electrode, wherein at least a portion of the third sensing electrode overlaps with the first sensing electrode in a normal direction of the circuit board without changing position, and the third sensing electrode does not contact the first sensing electrode and the second sensing electrode;
wherein, when the movable portion drives the second sensing electrode to move along the second direction, an area where the third sensing electrode and the circuit board overlap in the normal direction is changed.

4. The mechanical key component according to claim 3, wherein the third sensing electrode is electrically floating, and at least another portion of the third sensing electrode is located in the circuit board.

5. The mechanical key component according to claim 4, wherein the third sensing electrode includes a first portion overlapping with the first sensing electrode and a second portion not overlapping with the first sensing electrode, wherein the second portion is closer to the second sensing electrode than the first portion, and the first portion and the second portion overlap with the first sensing electrode and the second sensing electrode respectively at different positions in the first direction;
wherein, in response to the key cap being in the pressed position, the second portion overlaps with the second sensing electrode.

6. The mechanical key component according to claim 1, further comprising:
a fourth sensing electrode located in the circuit board, wherein the second sensing electrode is electrically floating, overlaps with the first sensing electrode and the fourth sensing electrode, and does not contact the first sensing electrode and the fourth sensing electrode.

7. The mechanical key component according to claim 1, further comprising:
a fifth sensing electrode fixed to the key cap, wherein at least a portion of the fifth sensing electrode overlaps with the first sensing electrode on a normal direction of the circuit board without being positionally changed, and the fifth sensing electrode does not contact the first sensing electrode and the second sensing electrode;
wherein, when the movable portion drives the second sensing electrode to move along the second direction, an area where the fifth sensing electrode and the circuit board overlap in the normal direction is changed.

8. The mechanical key component according to claim 1, wherein the key cap is moved between the unpressed position and the pressed position along a first direction, and the movable part drives the second sensing electrode to move relative to the first sensing electrode along the first direction.

9. A mechanical keyboard, comprising:
a plurality of mechanical key components, each including:
a circuit board with a first sensing electrode;
an elastic element disposed on the circuit board, wherein a movable portion of the elastic element is connected to a second sensing electrode; and
a key cap movably disposed on the elastic element, wherein the elastic element enables the key cap to move between an unpressed position and a pressed position, and the movable portion drives the second sensing electrode to move relative to the first sensing electrode without contacting the first sensing electrode;
a processing circuit electrically connected to the mechanical key components, wherein the processing circuit is configured to perform following processes:
providing a first sensing signal to at least one of the first sensing electrode and the second sensing electrode;
obtaining a coupling capacitance generated between the first sensing electrode and the second sensing electrode; and
detecting, in response to the key cap being moved between the unpressed position and the pressed position, a change in the coupling capacitance to indicate whether the key cap is in the unpressed position or the pressed position;
wherein, in response to the key cap moving between the unpressed position and the pressed position along a first direction, the movable portion drives the second sensing electrode to move relative to the first sensing electrode along a second direction, the second direction is parallel to a surface of the circuit board, and the first direction is perpendicular to the second direction.

10. The mechanical keyboard according to claim 9, wherein the second sensing electrode is fixed by a limiting element and moves only along the second direction, and the first sensing electrode is fixedly disposed on the circuit board.

11. The mechanical keyboard according to claim 9, wherein each of the mechanical key components further includes:
a third sensing electrode, wherein at least a portion of the third sensing electrode overlaps with the first sensing electrode in a normal direction of the circuit board without changing position, and the third sensing electrode does not contact the first sensing electrode and the second sensing electrode;
wherein, when the movable portion drives the second sensing electrode to move along the second direction, an area where the fifth sensing electrode and the circuit board overlap in the normal direction is changed.

12. The mechanical keyboard according to claim 11, wherein the third sensing electrode is electrically floating, and at least another portion of the third sensing electrode is located in the circuit board.

13. The mechanical keyboard according to claim 12, wherein the third sensing electrode includes a first portion overlapping with the first sensing electrode and a second portion not overlapping with the first sensing electrode, wherein the second portion is closer to the second sensing electrode than the first portion, and the first portion and the second portion overlap with the first sensing electrode and the second sensing electrode respectively at different positions in the first direction;
wherein, in response to the key cap being in the pressed position, the second portion overlaps with the second sensing electrode.

14. The mechanical keyboard according to claim 9, wherein each of the mechanical key components further includes:
a fourth sensing electrode located in the circuit board, wherein the second sensing electrode is electrically floating, overlaps with the first sensing electrode and the fourth sensing electrode, and does not contact the first sensing electrode and the fourth sensing electrode.

15. The mechanical keyboard according to claim 9, wherein each of the mechanical key components further includes:
a fifth sensing electrode fixed to the key cap, wherein at least a portion of the fifth sensing electrode overlaps with the first sensing electrode on a normal direction of the circuit board without a change in position, and the fifth sensing electrode does not contact the first sensing electrode and the second sensing electrode;
wherein, when the movable portion drives the second sensing electrode to move along the second direction, an area where the fifth sensing electrode and the circuit board overlap in the normal direction is changed.

16. The mechanical keyboard according to claim 9, wherein the key cap is moved between the unpressed position and the pressed position along a first direction, and the movable part drives the second sensing electrode to move relative to the first sensing electrode along the first direction.
